(19) United States
(12) Patent Application Publication
(10) Pub. No.: US 2009/0127642 A1
(43) Pub. Date: May 21, 2009

(54) PHOTOELECTRIC SURFACE, ELECTRON TUBE COMPRISING SAME, AND METHOD FOR PRODUCING PHOTOELECTRIC SURFACE

(75) Inventors: Shinichi Yamashita, Shizuoka (JP); Hiroyuki Watanabe, Shizuoka (JP); Hideaki Suzuki, Shizuoka (JP); Kengo Suzuki, Shizuoka (JP)

Correspondence Address: DRINKER BIDDLE & REATH (DC), 1500 K STREET, N.W., SUITE 1100, WASHINGTON, DC, 20005-1209, US

(73) Assignee: HAMAMATSU PHOTONICS K.K., Hamamatsu-shi (JP)

(21) Appl. No.: 12/281,720

(22) PCT Filed: Mar. 5, 2007
(86) PCT No.: PCT/JP2007/054206

§ 371 Date: Oct. 22, 2008

(30) Foreign Application Priority Data
Mar. 8, 2006 (JP) 2006-063031

(51) Int. Cl. H01L 31/02; H01J 43/04; H01L 21/04

(52) U.S. Cl. 257/431; 313/532; 438/57; 257/E31.11; 257/E21.04

(57) ABSTRACT

A photoelectric element 10 includes a substrate 12 that transmits incident light, an intermediate layer 14 made of HfO₂, an under layer 16, and a photoelectron emitting layer 18 containing an alkali metal. That is, the photoelectric element 10 includes the intermediate layer 14 formed between the substrate 12 and the photoelectron emitting layer 18. Thereby, a photoelectric element that can exhibit a high value of effective quantum efficiency, an electron tube including the same, and a method for producing a photoelectric element are realized.

### TECHNICAL FIELD

The present invention relates to a photoelectric element that emits photoelectrons to the outside upon an incidence of light, an electron tube including the same, and a method for producing a photoelectric element.

### BACKGROUND ART

A photoelectric surface is an element that emits electrons (photoelectrons) produced in response to light made incident, and has been used for, for example, a photomultiplier tube. For the photoelectric element, a photoelectron emitting layer is formed on a substrate, and incident light transmitted through the substrate is made incident into the photoelectron emitting layer, and therein photoelectrons are emitted (See Document 1: U.S. Pat. No. 3,254,253, for example).

Patent Document 1: Specification of U.S. Pat. No. 3,254,253

### DISCLOSURE OF THE INVENTION

### Problems to be Solved by the Invention

It is preferable that the sensitivity of a photoelectric element to incident light is high. For increasing the sensitivity of the photoelectric element, it is necessary to increase an effective quantum efficiency that indicates a ratio of the number of photoelectrons emitted out of the photoelectric element to the number of photons made incident into the photoelectric element including a substrate and a photoelectron emitting layer. For example, in Patent Document 1, a photoelectric surface including an antireflection film between the substrate and the photoelectron emitting layer has been studied. However, in the photoelectric element, a further improvement in quantum efficiency has been demanded.

It is an object of the present invention to provide a photoelectric element that can exhibit a high value of effective quantum efficiency, an electron tube including the same, and a method for producing a photoelectric element.

### Means for Solving the Problems

Meanwhile, the inventors of the present application have devoted themselves to continuous study of the subject in order to realize a photoelectric element having a high quantum efficiency, and discovered a new fact that the effective quantum efficiency declines in a photoelectric element with a photoelectron emitting layer containing an alkali metal as a result of this being exposed to a high temperature in manufacturing. The inventors of the present application have considered that the cause of such a decline in quantum efficiency exists in migration of the alkali metal from the photoelectron emitting layer to the substrate, and arrived at an idea of providing an intermediate layer made of hafnium oxide between the substrate and photoelectron emitting layer.

In accordance with such study results, a photoelectric element by the present invention includes a substrate that transmits incident light, a photoelectron emitting layer containing an alkali metal, and an intermediate layer formed between the substrate and the photoelectron emitting layer, wherein the intermediate layer is made of hafnium oxide.

Moreover, a method for producing a photoelectric element by the present invention includes a step of forming an intermediate layer made of hafnium oxide on a substrate that transmits incident light; and a step of forming a photoelectron emitting layer containing an alkali metal at a side of the intermediate layer opposite to a surface in contact with the substrate.

In the photoelectric element mentioned above, a decrease in effective quantum efficiency of the photoelectric element due to a heat treatment applied when this is manufactured is suppressed and it thus becomes possible to maintain a high quantum efficiency. This is considered to be caused by including the intermediate layer made of hafnium oxide (HfO₂) between the substrate and the photoelectron emitting layer and this intermediate layer functioning as a barrier layer to suppress the alkali metal from migrating from the photoelectron emitting layer to the substrate. Moreover, the intermediate layer made of hafnium oxide (HfO₂) inserted between the substrate and the photoelectron emitting layer functions as an antireflection film. Therefore, the reflectivity in a desired wavelength is reduced with respect to light to be made incident into the photoelectron emitting layer, and it becomes possible to exhibit a high effective quantum efficiency. Thus, in the photoelectric element mentioned above, it is possible to exhibit a high value of effective quantum efficiency. Here, the effective quantum efficiency means a quantum efficiency not only of the photoelectron emitting layer but also of the photoelectric element as a whole including the substrate and others. Accordingly, the effective quantum efficiency also reflects an element such as transmittance of the substrate.

Moreover, an electron tube by the present invention includes the photoelectric element mentioned above, an anode that collects electrons emitted from the photoelectric element, and a container that contains the photoelectric element and the anode. Using such a configuration allows realizing an electron tube excellent in sensitivity.

### EFFECTS OF THE INVENTION

The present invention can provide a photoelectric element that can exhibit a high value of effective quantum efficiency, an electron tube including the same, and a method for producing a photoelectric element.

### BRIEF DESCRIPTION OF THE DRAWINGS

FIG. 1 is a sectional view showing a configuration of a photoelectric element according to an embodiment by partial enlargement.

FIG. 2 is a view showing a sectional configuration of a photomultiplier tube according to an embodiment.

FIG. 3 is a view showing a step of forming an intermediate layer.

FIG. 4 is a view showing a step of sealing a container by a stem.

FIG. 5 is a view showing a step of forming an under layer.

FIG. 6 is a view showing a step of forming a photoelectron emitting layer.

FIG. 7 is a figure showing schematic diagrams for explaining that an intermediate layer functions as a barrier layer.

FIG. 8 is a graph showing temperature dependence of the quantum efficiency for an example and a comparative example.

FIG. 9 is a graph showing spectral sensitivity characteristics of an example and a comparative example, respectively.

FIG. 10 is a graph showing spectral sensitivity characteristics of an example and a comparative example, respectively.

FIG. 11 is a graph showing spectral sensitivity characteristics of an example and a comparative example, respectively.

FIG. 12 is a figure showing an AFM image of an Sb film according to an example and an AFM image of an Sb film according to a comparative example.

### DESCRIPTION OF THE SYMBOLS

10—Photoelectric element, 12—Substrate, 14—Intermediate layer, 16—Under layer, 18—Photoelectron emitting layer, 30—Photomultiplier tube, 32—Container, 34—Entrance window, 36—Focusing electrode, 38—Anode, 40—Multiplier section, 42—Dynode, 44—Stem pin, 50—EB device, 51—Evaporation source of HfO₂, 52—Container, 53—Sb evaporation source, 54—Alkali metal source, 55—Electrode, 56—Lead wire, 57—Stem plate, 58—Sb film.

### BEST MODES FOR CARRYING OUT THE INVENTION

Hereinafter, embodiments of a photoelectric element, an electron tube including the same, and a method for producing a photoelectric element according to the present invention will be described in detail along with the drawings. In addition, the same elements are denoted with the same reference symbols in descriptions of the drawings, and overlapping description will thus be omitted.

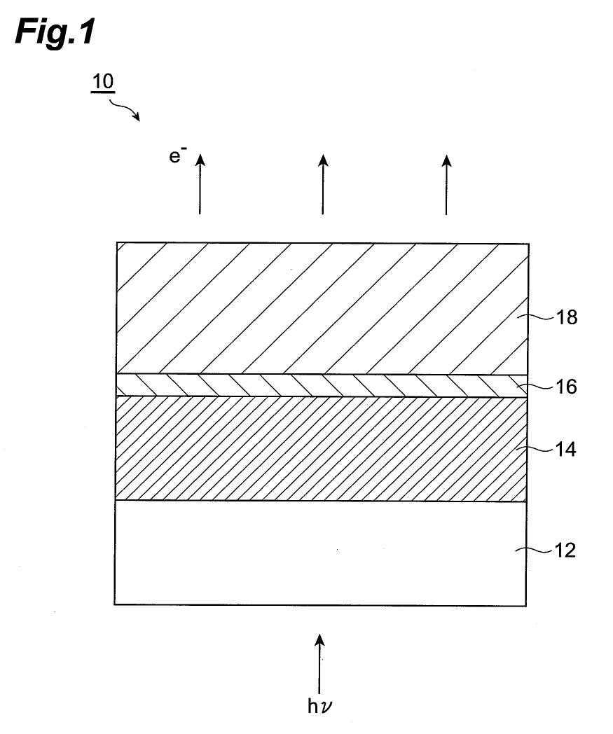

FIG. 1 is a sectional view showing a configuration of a photoelectric element according to an embodiment by partial enlargement. In this photoelectric element 10, as shown in FIG. 1, an intermediate layer 14, an under layer 16, and a photoelectron emitting layer 18 are formed on a substrate 12 in this order. In FIG. 1, the photoelectric element 10 is schematically illustrated as a transmission type from the substrate 12 side of which light hv is made incident and from the photoelectron emitting layer 18 side of which photoelectrons e⁻ are emitted.

The substrate 12 is formed of a substrate on which the intermediate layer 14 made of hafnium oxide (HfO₂) can be formed. For the substrate 12, one that transmits light with a wavelength of 300 nm to 1000 nm is preferable. Examples of this substrate include substrates made of quartz glass or borosilicate glass.

The intermediate layer 14 is formed of HfO₂. HfO₂ exhibits a high transmittance to light with a wavelength of 300 nm to 1000 nm. Moreover, HfO₂ miniaturizes an island structure of Sb when Sb is formed thereon. The film thickness of the intermediate layer 14 is in a range of, for example, 50 Å to 1000 Å (5 nm to 100 nm).

The under layer 16 is made of, for example, MnOₓ, MgO, or TiO₂. As the under layer 16, one that transmits light with a wavelength of 300 nm to 1000 nm is preferable. Alternatively, the photoelectron emitting layer 18 may be formed on the intermediate layer 14 without the under layer 16. The film thickness of the under layer 16 is in a range of, for example, 5 Å to 800 Å (0.5 nm to 80 nm).

The photoelectron emitting layer 18 is made of, for example, K—CsSb, Na—KSb, Na K—CsSb, or Cs—TeSb. The photoelectron emitting layer 18 functions as an active layer of the photoelectric element 10. The film thickness of the photoelectron emitting layer 18 is in a range of, for example, 50 Å to 2000 Å (5 nm to 200 nm).

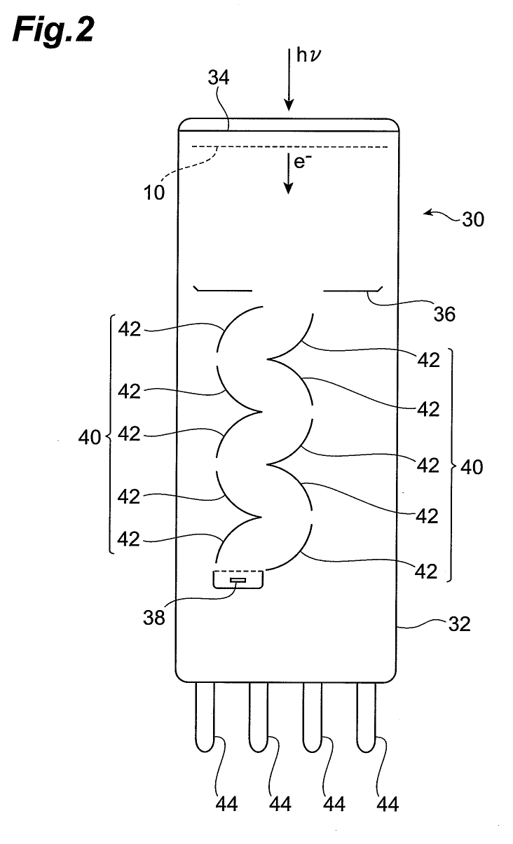

Next, an embodiment of an electron tube by the present invention will be described. FIG. 2 is a view showing a sectional configuration of a photomultiplier tube to which the photoelectric element 10 is applied as a transmission-type photoelectric surface. The photomultiplier tube 30 includes an entrance window 34 that transmits incident light and a container 32. In the container 32, provided is the photoelectric element 10 that emits photoelectrons, a focusing electrode 36 that leads emitted photoelectrons to a multiplier section 40, the multiplier section 40 that multiplies electrons, and an anode 38 that collects multiplied electrons. Thus, the container 32 contains the photoelectric element 10 and the anode 38. Also, in the photomultiplier tube 30, the substrate 12 of the photoelectric element 10 may be formed so as to function as the entrance window 34.

The multiplier section 40 provided between the focusing electrode 36 and the anode 38 is composed of a plurality of dynodes 42. Each electrode is electrically connected with a stem pin 44 provided so as to penetrate through the container 32.

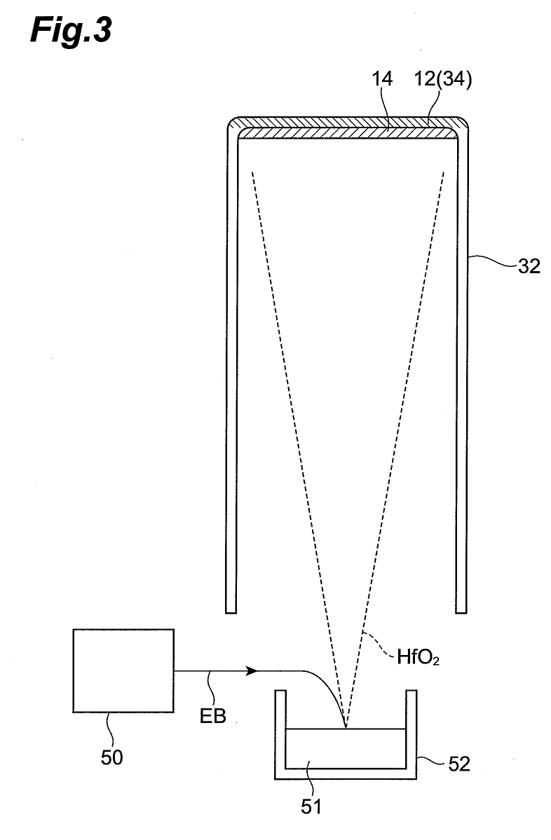

Next, a method for producing the photomultiplier tube 30 will be described based on FIG. 3 to FIG. 6. FIG. 3 to FIG. 6 are views schematically showing each step of the method for producing the photomultiplier tube 30.

First, referring to FIG. 3, description will be given of a step of forming an intermediate layer made of HfO₂ on a substrate. As shown in FIG. 3, HfO₂ is evaporated on a substrate part 12 corresponding to the entrance window 34 of the container 32 of a glass bulb applied with a cleaning treatment. Evaporation is performed by, for example, an EB evaporation method using an EB (electron beam) evaporation device 50. More specifically, in the vacuum container, an evaporation source 51 of HfO₂ housed in a container 52 is evaporated by heating with electron beams and this is made to grow as a thin film on the substrate part 12 heated by a heater. Thereby, the intermediate layer 14 made of HfO₂ is formed on the substrate part 12.

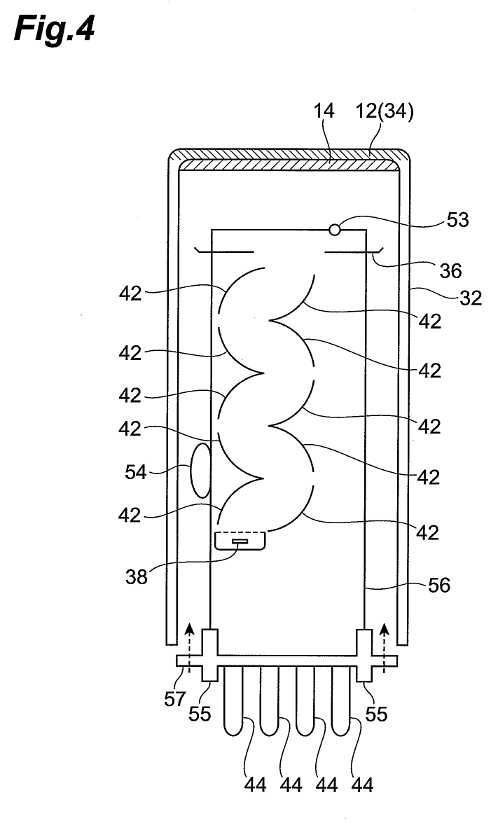

Next, as shown in FIG. 4, prepared is a stem plate 57 for which the focusing electrode 36 including an Sb evaporation source 53, the dynodes 42, and an alkali metal source 54 are integrally assembled. To the stem plate 57, fixed in a penetrating state are a plurality of stem pins 44 to supply a control voltage to each electrode. The Sb evaporation source 53 and the alkali metal source 54 are connected via a lead wire 56 to electrodes 55 fixed to the stem plate 57 in a penetrating state. The stem plate 57 and the container 32 thus prepared are sealed.

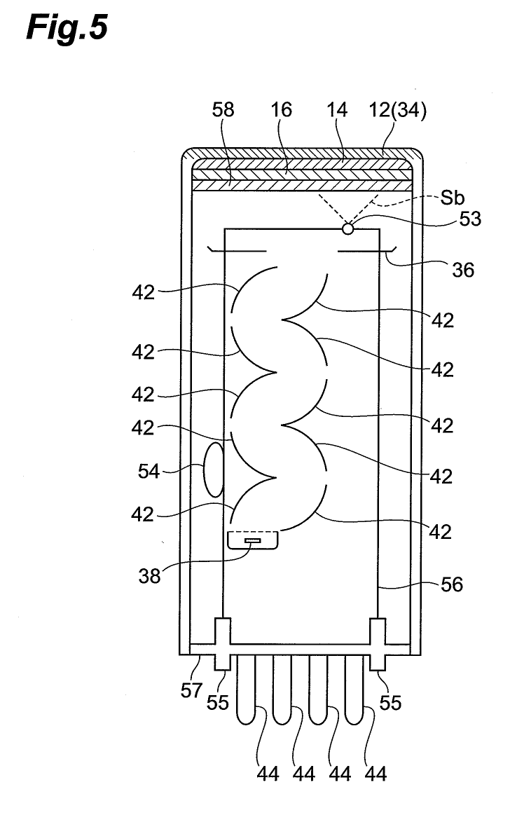

Next, as shown in FIG. 5, on the intermediate layer 14 formed on the substrate part 12 of the container 32, MnOₓ is evaporated to form the under layer 16. Further, by heating the Sb evaporation source 53 by supplying electricity, Sb is evaporated on the under layer 16 to form an Sb film 58.

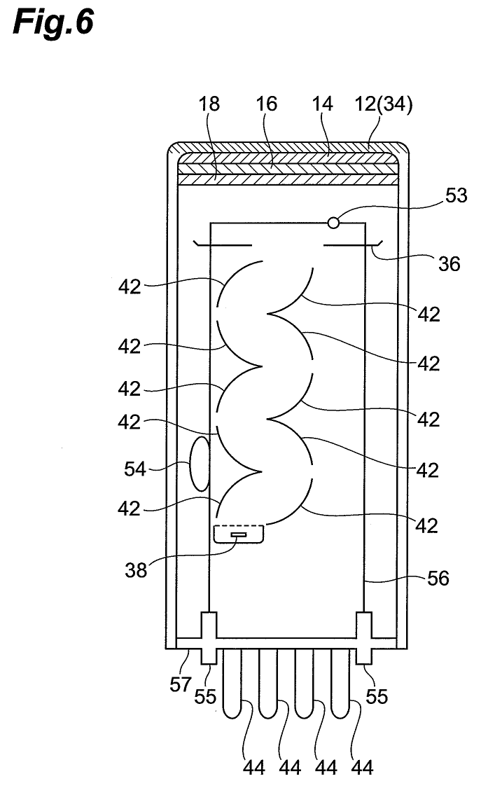

Next, referring to FIG. 6, description will be given of a step of forming a photoelectron emitting layer. An alkali metal (for example, K, Cs) vapor is fed to the Sb film 58 and the dynodes 42 to apply an activation treatment. At this time, the alkali metal vapor is fed, to the intermediate layer 14, at the side of the intermediate layer 14 opposite to a surface in contact with the substrate part 12. Thereby, the photoelectron emitting layer (film made of, for example, K—Cs—Sb) 18 containing an alkali metal (for example, K, Cs) is formed.

By the above producing method, the photoelectric element 10 and the photomultiplier tube 30 including the photoelectric element 10 are formed.

Operations of the photoelectric element 10 and the photomultiplier tube 30 will now be described. In the photomultiplier tube 30, incident light hv transmitted through the entrance window 34 is made incident into the photoelectric element 10. The light hv is made incident from the substrate 12 side, transmitted through the substrate 12, the intermediate layer 14, and the under layer 16, and reaches the photoelectron emitting layer 18. The photoelectron emitting layer 18 functions as an active layer, and therein photons are absorbed and photoelectrons e⁻ are produced. The photoelectrons e⁻ produced in the photoelectron emitting layer 18 are emitted from the surface of the photoelectron emitting layer 18. The emitted photoelectrons e⁻ are multiplied in the multiplier section 40 and collected by the anode 38.

In the photoelectric element 10, a decrease in effective quantum efficiency of the photoelectric element due to a heat treatment applied when this is manufactured is suppressed and it thus becomes possible to maintain a high quantum efficiency. This is considered to be caused by the fact that the element includes the intermediate layer 14 made of HfO₂ between the substrate 12 and the photoelectron emitting layer 18 and this intermediate layer 14 functions as a barrier layer to suppress the alkali metal from migrating from the photoelectron emitting layer 18 to the substrate 12. The sensitivity of the photoelectron emitting layer 18 is lowered when the alkali metal migrates, and further, the substrate 12 is colored by the alkali metal arrived by migrating to lower transmittance. Therefore, by suppressing migration of the alkali metal to the substrate 12, an increase in sensitivity of the photoelectron emitting layer 18 and an improvement in transmittance of the substrate 12 can be attained, and it consequently becomes possible to maintain a high quantum efficiency.

HfO₂ that forms the intermediate layer 14 has a very dense structure and is thus considered less likely to pass the alkali metal. Therefore, HfO₂ is very favorable as a material to form the intermediate layer 14 for which expected is a function as a barrier layer to suppress the alkali metal from migrating from the photoelectron emitting layer 18 to the substrate 12.

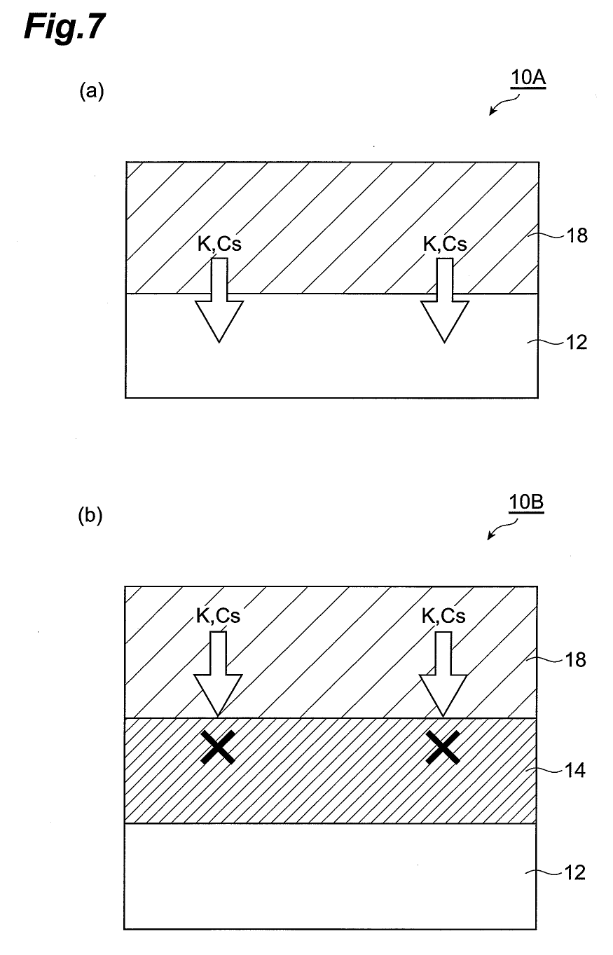

FIG. 7 shows schematic diagrams for explaining a concept that the intermediate layer 14 functions as a barrier layer. As shown in a configuration (a) of FIG. 7, in a photoelectric element 10A without the intermediate layer 14, that is, a photoelectric element 10A formed of the substrate 12 and the photoelectron emitting layer 18, an alkali metal (for example, K, Cs) contained in the photoelectron emitting layer 18 is considered to migrate to the substrate 12 at the time of heat treatment in the manufacturing process. A decrease in effective quantum efficiency is assumed to be due to the effect thereof.

On the other hand, as shown in a configuration (b) of FIG. 7, in a photoelectric element 10B including the intermediate layer 14, the intermediate layer 14 is considered to suppress an alkali metal (for example, K, Cs) contained in the photoelectron emitting layer 18 from migrating to the substrate 12 at the time of heat treatment in the manufacturing process. It is assumed that a high effective quantum efficiency can be realized in the photoelectric surface including the intermediate layer due to the effect thereof.

When a plurality of types of alkali metal are contained in the photoelectron emitting layer, an alkali vapor must be fed a plurality of times. Therefore, suppression of a decrease in quantum efficiency due to a heat treatment is very effective.

The photoelectric element 10 includes the intermediate layer 14 between the substrate 12 and the photoelectron emitting layer 18. Therefore, appropriately controlling the film thickness of the intermediate layer 14 makes it possible to reduce reflectivity with respect to light with a desired wavelength. As a result of the intermediate layer 14 thus functioning as an antireflection film, it becomes possible to exhibit a high effective quantum efficiency.

The photoelectric element 10 includes the under layer 16. In this case, it becomes possible to form, as a further homogeneous film, the Sb film 58 to be evaporated on the under layer 16 when forming the photoelectron emitting layer 18. Also, the photoelectric element 10 may not include the under layer 16.

The photomultiplier tube 30 includes the photoelectric element 10 exhibiting a high effective quantum efficiency as mentioned above. Therefore, a photomultiplier tube excellent in sensitivity can be realized.

Subsequently, concrete samples A to C of photoelectric elements and samples D to F of comparative examples will be described. Samples A to C and samples D to F differ in the material to form a photoelectron emitting layer, respectively. None of samples D to F include an intermediate layer made of HfO₂. Moreover, quantum efficiencies measured for these samples correspond to the effective quantum efficiency described above.

Concretely, sample A includes a substrate made of quartz glass, an intermediate layer made of HfO₂, and a photoelectron emitting layer made of Na—K—CsSb. On the other hand, sample D, which is a comparative example to sample A, includes a substrate made of quartz glass and a photoelectron emitting layer made of Na—K—CsSb.

Moreover, sample B includes a substrate made of borosilicate glass, an intermediate layer made of HfO₂, and a photoelectron emitting layer made of Na—KSb. On the other hand, sample E, which is a comparative example to sample B, includes a substrate made of borosilicate glass and a photoelectron emitting layer made of Na—KSb.

Moreover, sample C includes a substrate made of borosilicate glass, an intermediate layer made of HfO₂, an under layer made of MnOₓ, and a photoelectron emitting layer made of K—CsSb. On the other hand, sample F, which is a comparative example to sample C, includes a substrate made of borosilicate glass, an under layer made of MnOₓ, and a photoelectron emitting layer made of K—CsSb.

HfO₂ has a refractive index of approximately 2.05, which is an intermediate value between a refractive index of the substrate (quartz glass or borosilicate glass) and a refractive index of the photoelectron emitting layer (Na—K—CsSb, or Na—KSb, or K—CsSb), in these samples A to F.

The following Table 1 shows measurement results of an alkali content (wt %) of the substrate in the photoelectric element of sample E, including the substrate made of borosilicate glass and a photoelectron emitting layer made of Na—KSb, measured at a photoelectron emitting layer side and an opposite side thereto. Here, the measurement results shown in Table 1 are results measured after washing away the alkali metal adhered to the surface of the substrate. Moreover, ZKN7 (manufactured by Schott) was used as the substrate of sample E.

TABLE 1

| | photoelectron | side opposite to |
|---|---|---|
| | emitting layer side | photoelectron emitting layer |
| color | brown | transparent |
| Si (wt. %) | 49.6 | 49.5 |
| O (wt. %) | 31.0 | 39.3 |
| Zn (wt. %) | 6.78 | 5.62 |
| K (wt. %) | 6.16 | 0.15 |
| Na (wt. %) | 3.14 | 2.41 |
| Al (wt. %) | 2.25 | 2.01 |
| Ca (wt. %) | 0.49 | 0.46 |
| Cl (wt. %) | 0.31 | 0.23 |
| As (wt. %) | 0.25 | 0.25 |

It can be understood from Table 1 that the amount of the contained alkali metal (K, Na) greatly differs between the photoelectron emitting layer side and the opposite side thereto, and the amount is larger at the photoelectron emitting layer side. Further, the side opposite to the photoelectron emitting layer of sample E remained transparent without being colored, while the photoelectron emitting layer side was colored in brown. This is considered to be because the alkali metal (K, Na) contained in the photoelectron emitting layer migrated to the substrate due to a heat treatment in manufacturing.

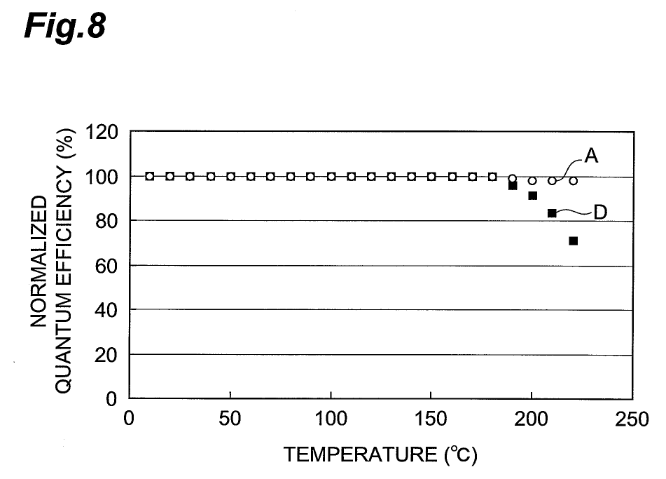

FIG. 8 is a graph showing temperature dependence of the quantum efficiency when sample A and sample D were fired. The horizontal axis of the graph shown in FIG. 8 indicates the firing temperature (° C.) and the vertical axis indicates the normalized quantum efficiency (%). The normalized quantum efficiency means the value of a normalized quantum efficiency at each temperature for each sample, while providing a quantum efficiency at the time where the firing temperature is 10° C. as 100%. Here, shown are results of normalized quantum efficiencies when the firing temperature was changed from 10° C. to 220° C. by 10° C. increments, determined for each sample. In the graph shown in FIG. 8, values for sample A are plotted with circles, and values for sample D are plotted with squares.

According to FIG. 8, sample D is reduced in the value of normalized quantum efficiency after the firing temperature exceeds 180° C., and this decreases to exhibit a normalized quantum efficiency of 71.2% at 220° C. On the other hand, it can be understood that sample A exhibits an almost constant normalized quantum efficiency until the firing temperature reaches 220° C., and this maintains a normalized quantum efficiency of 98.3% even at 220° C. Thus, it is clearly shown that sample A including the intermediate layer never decreases quantum efficiency even when the firing temperature is raised. Since the temperature is raised to approximately 200° C. or more in the process of manufacturing a photoelectric element, the fact that the quantum efficiency does not decrease even over 200° C. is very effective in finally obtaining a photoelectric element exhibiting a high quantum efficiency. As a result, it can be understood that a decrease in quantum efficiency is suppressed in sample A even when a heat treatment is applied thereto in manufacturing.

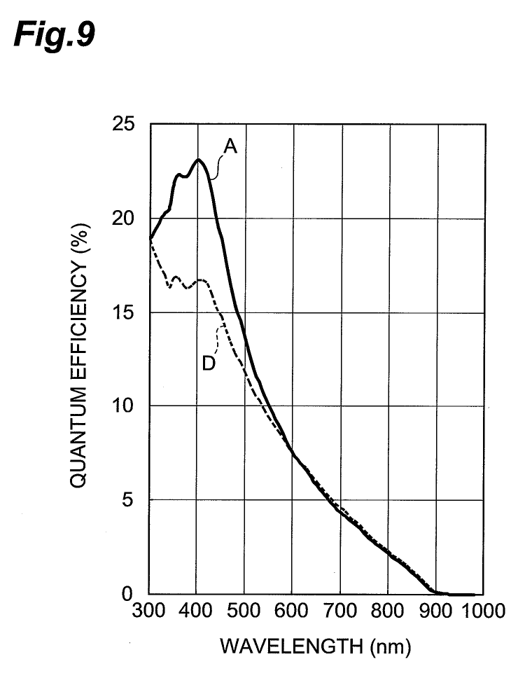

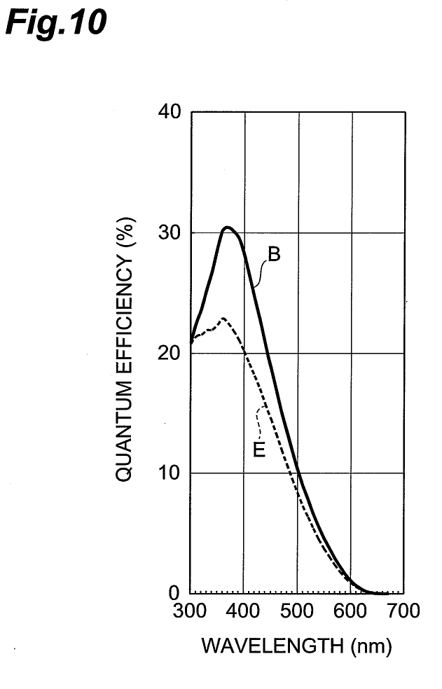

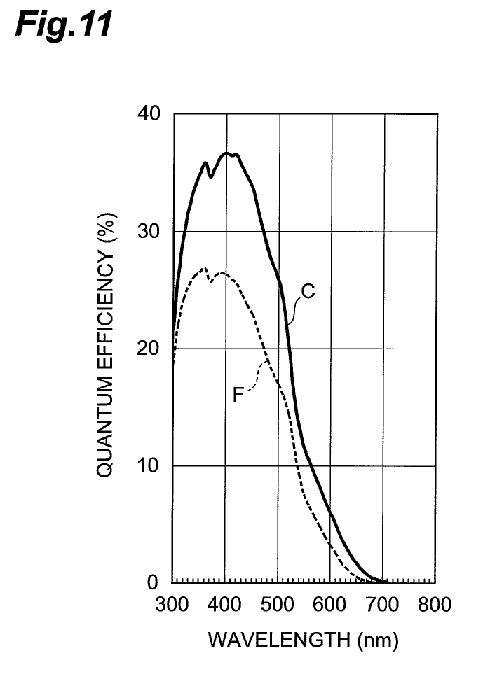

FIG. 9 to FIG. 11 show spectral sensitivity characteristics of samples A to F. FIG. 9 is a graph showing quantum efficiencies with respect to the wavelength for sample A and sample D, and FIG. 10 is a graph for sample B and sample E, and FIG. 11 is a graph for sample C and sample F. The horizontal axis of the graph shown in each of FIG. 9 to FIG. 11 indicates the wavelength (nm) and the vertical axis indicates the quantum efficiency (%). The graph plotted by a solid line in FIG. 9 represents sample A, and the graph plotted by a dotted line represents sample D, the graph plotted by a solid line in FIG. 10 represents sample B, and the graph plotted by a dotted line represents sample E, and the graph plotted by a solid line in FIG. 11 represents sample C, and the graph plotted by a dotted line represents sample F.

As can be understood from FIG. 9, sample A exhibits a higher quantum efficiency than that of sample D for light within a wavelength range of 300 nm to 1000 nm. Concretely, for example, sample A exhibits a quantum efficiency of approximately 23.1% to light with a wavelength of 400 nm, and the sample D, a quantum efficiency of approximately 16.7%, sample A thus exhibiting a quantum efficiency increased by approximately 40% from that of sample D.

Moreover, as can be understood from FIG. 10, sample B exhibits a higher quantum efficiency than that of sample E for light within a wavelength range of 300 nm to 700 nm. Concretely, for example, sample B exhibits a quantum efficiency of 30.4% to light with a wavelength of 370 nm, and the sample E, a quantum efficiency of 22.9%, sample B thus exhibiting a quantum efficiency increased by approximately 30% from that of sample E.

Moreover, as can be understood from FIG. 11, sample C exhibits a higher quantum efficiency than that of sample F for light within a wavelength range of 300 nm to 700 nm. Concretely, for example, sample C exhibits a quantum efficiency of 36.5% to light with a wavelength of 420 nm, and the sample F, a quantum efficiency of 25.6%, sample C thus exhibiting a quantum efficiency increased by approximately 40% from that of sample F.

Subsequently, the quantum efficiency of a photoelectric element including a substrate, an intermediate layer made of HfO₂, and a photoelectron emitting layer made of Na—K and the quantum efficiency of a photoelectric element including a substrate and a photoelectron emitting layer and not including an intermediate layer were measured, respectively. The results are shown in Table 2. In the measurements, light with a wavelength of 370 nm was used as an incident light.

TABLE 2

| | with | without |
|---|---|---|
| | intermediate layer | intermediate layer |
| quantum efficiency | 30.1 | 24.4 |
| (measured value) (%) | 28.7 | 21.3 |
| | 26.2 | 22.5 |
| | 28.5 | |
| | 26.8 | |
| | 28.1 | |
| | 28.4 | |
| | 28.3 | |
| | 28.2 | |
| | 27.9 | |
| | 25.7 | |
| | 26.7 | |
| | 28.0 | |
| | 29.3 | |
| | 30.5 | |
| | 28.9 | |
| | 28.5 | |
| | 27.5 | |
| | 29.2 | |
| | 26.5 | |
| | 30.1 | |
| | 30.7 | |
| | 30.0 | |
| quantum efficiency | 28.4 | 22.7 |
| (average value) (%) | | |

With regard to the photoelectric element including an intermediate layer, 23 samples were prepared and measurements were performed. With regard to the photoelectric element not including an intermediate layer, 3 samples were prepared and measurements were performed. Consequently, as can be understood from Table 2, in the photoelectric elements including intermediate layers, an average value reached 28.4%, while in the photoelectric elements not including intermediate layers, an average value merely reached 22.7%. Accordingly, it can be clearly understood from Table 2 that a photoelectric element can realize a high quantum efficiency by including an intermediate layer made of HfO₂.

Further, the quantum efficiency of a photoelectric element including a substrate, an intermediate layer made of HfO₂, and a photoelectron emitting layer made of K—Cs and the quantum efficiency of a photoelectric element including a substrate and a photoelectron emitting layer made of K—Cs and not including an intermediate layer were measured, respectively. In the measurements, light with a wavelength of 420 nm was used as an incident light. With regard to the photoelectric element including an intermediate layer, 9 samples were prepared, and with regard to the photoelectric element not including an intermediate layer, 1 sample was prepared. Of quantum efficiencies obtained from these samples, average values were determined for the photoelectric elements including intermediate layers and the photoelectric element not including an intermediate layer, respectively, and the results are shown in Table 3.

TABLE 3

| | with | without |
|---|---|---|
| | intermediate layer | intermediate layer |
| quantum efficiency | 36.2 | 27.6 |
| (average value) (%) | | |

As can be understood from Table 3, in the photoelectric elements including intermediate layers, the average value reached 36.2%, while in the photoelectric element not including an intermediate layer, the average value merely reached 27.6%. Accordingly, it can be understood from Table 3 that a photoelectric element can realize a high quantum efficiency by including an intermediate layer made of HfO₂.

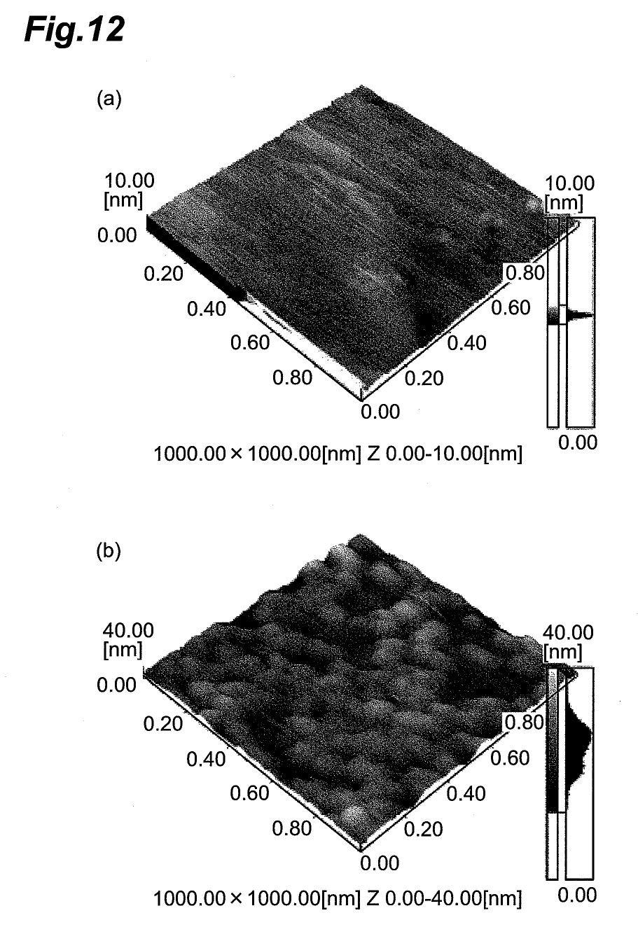

Moreover, (a) in FIG. 12 shows an AFM image of an Sb film surface formed on an intermediate layer of a glass substrate formed with the intermediate layer made of HfO₂, and (b) in FIG. 12 shows an AFM image of an Sb film surface formed on a glass substrate. The AFM image means an image obtained by an atomic force microscope (AFM). It can be understood from FIG. 12 that the Sb film (FIG. 12(a)) having thereunder an intermediate layer is flat and spatially homogeneous in comparison with the Sb film (FIG. 12(b)) not having an intermediate layer. Thus including an intermediate layer made of HfO₂ allows obtaining a homogeneous Sb film, and an alkali metal vapor can be accordingly reacted with the homogeneous Sb film to form a photoelectron emitting layer. Consequently, a high-quality photoelectron emitting layer with little formation of defect areas such as grain boundaries can be obtained, and this can be considered to contribute to an improvement in quantum efficiency.

In the above, preferred embodiments of the present invention have been described, however, the present invention is by no means limited to the above-mentioned embodiments and various modifications can be made. For example, the substances contained in the substrate 12, the under layer 16, and the photoelectron emitting layer 18 are not limited to the substances described in the foregoing. The photoelectric element 10 may not include the under layer 16. The methods for forming the intermediate layer 14, the under layer 16, and the photoelectron emitting layer 18 of the photoelectric element 10 are not limited to the methods described in the above-mentioned embodiment, respectively.

Moreover, the type of alkali metal contained by the photoelectron emitting layer 18 is not limited to cesium (Cs), potassium (K), and sodium (Na) described in the above-mentioned embodiment and may be, for example, rubidium (Rb) or lithium (Li). Moreover, the number of types of alkali metal contained by the photoelectron emitting layer 18 may be one type, or two types (bialkali), or three types or more (multialkali). Moreover, the film thicknesses of the intermediate layer 14, the under layer 16, and the photoelectron emitting layer 18 of the photoelectric element 10 are not limited to the thicknesses exemplified in the above-mentioned embodiment. Moreover, in the methods for producing a photoelectric element and samples according to the above-mentioned embodiment, examples made of MnOₓ have been shown as the under layer 16, however, this is not limited to MnOₓ as exemplified in the description of the photoelectric element 10 and may be an under layer made of, for example, MgO or TiO₂.

Moreover, a photoelectric element of the present invention may be applied to electron tubes such as a photoelectric tube and an image intensifier (I.I. tube) besides a photomultiplier tube.

A photoelectric element according to the above-mentioned embodiment uses a configuration including a substrate that transmits incident light, a photoelectron emitting layer containing an alkali metal, and an intermediate layer formed between the substrate and the photoelectron emitting layer, wherein the intermediate layer is made of hafnium oxide.

Moreover, a method for producing a photoelectric element according to the above-mentioned embodiment uses a configuration including a step of forming an intermediate layer made of hafnium oxide on a substrate that transmits incident light and a step of forming a photoelectron emitting layer containing an alkali metal at a side of the intermediate layer opposite to a surface in contact with the substrate.

Here, an under layer may be formed between the intermediate layer and the photoelectron emitting layer. In this case, it becomes possible to form an Sb film to be formed when forming the photoelectron emitting layer as a further homogeneous film.

It is preferable that the photoelectron emitting layer is a compound of antimony (Sb) and the alkali metal. It is preferable that the alkali metal is cesium (Cs), potassium (K), or sodium (Na).

Moreover, an electron tube according to the above-mentioned embodiment uses a configuration including the photoelectric element mentioned above, an anode that collects electrons emitted from the photoelectric element, and a container that stores the photoelectric element and the anode. Using such a configuration allows realizing an electron tube excellent in sensitivity.

### INDUSTRIAL APPLICABILITY

The present invention can be used as a photoelectric element that can exhibit a high value of effective quantum efficiency, an electron tube including the same, and a method for producing a photoelectric element.

1: A photoelectric element comprising a substrate that transmits incident light, a photoelectron emitting layer containing an alkali metal, and an intermediate layer formed between the substrate and the photoelectron emitting layer, wherein the intermediate layer is made of hafnium oxide.

2: The photoelectric element according to claim 1, wherein an under layer is formed between the intermediate layer and the photoelectron emitting layer.

3: The photoelectric element according to claim 1, wherein the photoelectron emitting layer is a compound of antimony and the alkali metal.

4: The photoelectric element according to claim 1, wherein the alkali metal is cesium, potassium, or sodium.

5: An electron tube comprising:
the photoelectric element according to claim 1;
an anode that collects electrons emitted from the photoelectric element; and
a container that contains the photoelectric element and the anode.

6: A method for producing a photoelectric element comprising:
a step of forming an intermediate layer made of hafnium oxide on a substrate that transmits incident light; and
a step of forming a photoelectron emitting layer containing an alkali metal at a side of the intermediate layer opposite to a surface in contact with the substrate.

7: The photoelectric element according to claim 1, wherein the photoelectron emitting layer is made of Na—K—CsSb.

8: The photoelectric element according to claim 1, wherein the photoelectron emitting layer is made of Na—KSb.

9: The photoelectric element according to claim 1, wherein the photoelectron emitting layer is made of K—CsSb.
